(19) United States
(12) Patent Application Publication
(10) Pub. No.: US 2004/0003838 A1
(43) Pub. Date: Jan. 8, 2004

(54) Nano photovoltaic/solar cells

(76) Inventor: Lawrence F. Curtin, Key Biscayne, FL (US)

Correspondence Address: Richard C. Litman, LITMAN LAW OFFICES, LTD., P.O. Box 15035, Arlington, VA, 22215, US

(21) Appl. No.: 10/189,219

(22) Filed: Jul. 5, 2002

(51) Int. Cl. H01L 31/00

(52) U.S. Cl. 136/250; 136/256; 438/63

(57) ABSTRACT

Nano photovoltaic/solar cells each include a layer of plastic, conductive paint on the layer of plastic, glue on the conductive paint, nanocone photovoltaic/solar elements in the glue and contacting the conductive paint, clear conductive coating on the nanocone photovoltaic/solar elements, and a contact transfer release sheet on the clear conductive coating. The nanocone photovoltaic/solar elements each include a conductive bottom, a P type layer on the conductive bottom, an N type layer on the P type layer, and a clear conductive top on the N type layer. The nanocone photovoltaic/solar elements may include more than one P and N junction between the conductive bottom and clear conductive top.

### CROSS REFERENCE TO RELATED APPLICATIONS

This application is related to the following patents, the subject matter of which are hereby incorporated by reference: U.S. Pat. No. 6,013,871, entitled METHOD OF PREPARING A PHOTOVOLTAIC DEVICE, U.S. Pat. No. 6,160,215, entitled METHOD OF MAKING PHOTOVOLTAIC DEVICE, and U.S. Pat. No. 6,380,477 B1, entitled METHOD OF MAKING PHOTOVOLTAIC DEVICE.

### BACKGROUND OF THE INVENTION

1. Field of the Invention

The present invention relates to photovoltaic/solar cells and, more particularly to photovoltaic/solar cells configured using nanotechnology.

2. Description of the Related Art

The use of photovoltaic or solar cells, devices that can absorb and convert light into electrical power, has been limited because of high production costs. Even the fabrication of the simplest semiconductor cell is a complex process that has to take place under exactly controlled conditions, such as high vacuum and temperatures between 400° C. and 1,400° C. A need exists for providing inexpensive manufacturing processes for manufacturing photovoltaic/solar cells. The related art is represented by the following references of interest.

U.S. Pat. No. 4,228,570, issued on Oct. 21, 1980 to Rhodes R. Chamberlain et al., describes an apparatus for forming a large area photovoltaic panel into a plurality of smaller photovoltaic cells. Chamberlain et al. does not suggest nano photovoltaic/solar cells according to the claimed invention.

U.S. Pat. No. 4,260,429, issued on Apr. 7, 1981 to Richard L. Moyer, describes an electrode for a photovoltaic cell and a method for its manufacture. Moyer does not suggest nano photovoltaic/solar cells according to the claimed invention.

U.S. Pat. No. 4,283,591, issued on Aug. 11, 1981 to Karl W. Böer, describes a photovoltaic cell and a method for its manufacture. Böer does not suggest nano photovoltaic/solar cells according to the claimed invention.

U.S. Pat. No. 4,368,216, issued on Jan. 11, 1983 to Manassen et al., describes a semiconductor photoelectrode and a method for its manufacture. Manassen et al. does not suggest nano photovoltaic/solar cells according to the claimed invention.

U.S. Pat. No. 4,759,993, issued on Jul. 26, 1988 to Purchandra Pai et al., describes a coated stainless steel article and a method for its manufacture. Pai et al. does not suggest nano photovoltaic/solar cells according to the claimed invention.

U.S. Pat. No. 5,084,107, issued on Jan. 28, 1992 to Mikio Deguchi et al., describes a solar cell electrode structure and a method for its manufacture. Deguchi et al. does not suggest nano photovoltaic/solar cells according to the claimed invention.

U.S. Pat. No. 5,380,371, issued on Jan. 10, 1995 to Tsutomu Murakami, describes a thin film solar cell and a method for its manufacture. Murakami does not suggest nano photovoltaic/solar cells according to the claimed invention.

U.S. Pat. No. 5,389,159, issued on Feb. 14, 1995 to Ichiro Kataoka et al., describes a solar cell module and a method for its manufacture. Kataoka et al. does not suggest nano photovoltaic/solar cells according to the claimed invention.

U.S. Pat. No. 5,428,249, issued on Jun. 27, 1995 to Ippei Sawayama et al., describes a photovoltaic device which has high conversion efficiency and can stably operate over long periods of time. Sawayama et al. does not suggest nano photovoltaic/solar cells according to the claimed invention.

U.S. Pat. No. 5,487,792, issued on Jan. 30, 1996 to David E. King et al., describes a protective diffusion barrier having adhesive qualities for metalized surfaces. King et al. does not suggest nano photovoltaic/solar cells according to the claimed invention.

U.S. Pat. No. 5,641,362, issued on Jun. 24, 1997 to Daniel L. Meier, describes an aluminum alloy junction self-aligned back contact silicon solar cell and a method for its manufacture. Meier does not suggest nano photovoltaic/solar cells according to the claimed invention.

U.S. Pat. Nos. 5,681,402 and 5,861,324, issued on Oct. 28, 1997 and Jan. 19, 1999, respectively, to Hirofumi Ichinose et al., describe a photovoltaic element and a method for its manufacture. Ichinose et al. '402 and '324 do not suggest nano photovoltaic/solar cells according to the claimed invention.

U.S. Pat. No. 6,008,451, issued on Dec. 28, 1999 to Hirofumi Ichinose et al., describes a photovoltaic device which has high humidity resistance and high reliability throughout a long term use. Ichinose et al. '451 does not suggest nano photovoltaic/solar cells according to the claimed invention.

U.S. Pat. Nos. 6,013,871, 6,160,215, and 6,380,477 B1, issued on Jan. 11, 2000, Dec. 12, 2000, and Apr. 30, 2002, respectively, to Lawrence F. Curtin, describe a photovoltaic device and a method for its manufacture. Curtin '871, '215, and '477 do not suggest nano photovoltaic/solar cells according to the claimed invention.

U.S. Pat. No. 6,051,778, issued on Apr. 18, 2000 to Hirofumi Ichinose et al., describes an electrode structure, a method for its manufacture, and a photo-electricity generating device including the electrode. Ichinose et al. '778 does not suggest nano photovoltaic/solar cells according to the claimed invention.

U.S. Pat. No. 6,093,884, issued on Jul. 25, 2000 to Fumitaka Toyomura et al., describes a solar cell array including a plurality of solar cell modules each including a solar cell element and an electroconductive outer portion. Toyomura et al. does not suggest nano photovoltaic/solar cells according to the claimed invention.

U.S. Pat. No. 6,121,542, issued on Sep. 19, 2000 to Hidenori Shiotsuka et al., describes a photovoltaic device and a method for its manufacture. Shiotsuka et al. does not suggest nano photovoltaic/solar cells according to the claimed invention.

U.S. Pat. No. 6,194,650 B1, issued on Feb. 27, 2001 to Hiroaki Wakayama et al., describes a coated object and a method for its manufacture. Wakayama et al. does not suggest nano photovoltaic/solar cells according to the claimed invention.

U.S. Pat. Nos. 6,206,996 B1 and 6,278,053 B1, issued on Mar. 27, 2001 and Aug. 21, 2001, respectively, to Jack I. Hanoka et al., describe decals and methods for providing an antireflective coating and metallization on a solar cell. Hanoka et al. '996 and '053 do not suggest nano photovoltaic/solar cells according to the claimed invention.

U.S. Pat. No. 6,224,016 B1, issued on May 1, 2001 to Yee-Chun Lee et al., describes an integrated flexible solar cell and a method for its manufacture. Lee et al. does not suggest nano photovoltaic/solar cells according to the claimed invention.

U.S. Pat. No. 6,284,072 B1, issued on Sep. 4, 2001 to Timothy G. Ryan et al., describes multifunctional microstructures and their preparation techniques. Ryan et al. does not suggest nano photovoltaic/solar cells according to the claimed invention.

European Patent document EP 0 710 990 A2, published on May 8, 1995, describes a photovoltaic device and a method for its manufacture. European '990 does not suggest nano photovoltaic/solar cells according to the claimed invention.

None of the above inventions and patents, taken either singularly or in combination, is seen to describe the instant invent-ion as claimed.

### SUMMARY OF THE INVENTION

The present invention is a method and apparatus for producing nano photovoltaic/solar cells. The nano photovoltaic/solar cells each include a layer of plastic, conductive paint on the layer of plastic, glue on the conductive paint, nanocone photovoltaic/solar elements in the glue and contacting the conductive paint, clear conductive coating on the nanocone photovoltaic/solar elements, and a contact transfer release sheet on the clear conductive coating.

The nanocone photovoltaic/solar elements each include a conductive bottom, a P type layer on the conductive bottom, an N type layer on the P type layer, and a clear conductive top on the N type layer. The nanocone photovoltaic elements may include more than one P and N junction between the conductive bottom and the clear conductive top.

The nanocone photovoltaic/solar elements are produced by employing a die with openings defined therein that are configured in the form of cones each having a rounded bottom and a side that ends at an opening on a surface of the die. The bottom of the opening has a smaller diameter than the top of the opening. The nanocone photovoltaic/solar elements are created by pouring in molten materials into the die, injecting into the die materials in a vapor stage, placing the die in an environment that includes a vapor cloud, or by pressing in heated materials. Materials that may be used as the conductive bottom include copper, brass, aluminum, molybdenum, or another conductive material.

A P type layer is formed by pouring in, injecting in, or hot pressing in, a P type material such as cadmium selenium (CdSe), P doped silicon, P doped gallium, or another P type material, in the die over the conductive bottom. An N type layer is formed by pouring in, injecting in, or hot pressing in, an N type material such as cadmium sulfate (CdS), N doped silicon, N doped gallium, or another N type of material, in the die over the P type layer. The next step is to pour in, inject in, vapor deposit, or hot press in, a clear conductive material such as zinc oxide doped with aluminum or another clear conductive material. This process is not limited to a single junction such as described above but may include multiple P and N junctions using different materials between the conductive bottom and the clear conductive top if desirable.

Once nanocone photovoltaic/solar elements are produced, nanocone photovoltaic/solar cells may be manufactured by the following steps. Initially, a sheet of plastic is provided and the sheet is sprayed with a conductive paint. Glue is then sprayed on the conductive paint. The nanocone photovoltaic/solar elements are then attached in the glue and contact the conductive paint. Clear conductive coating is then sprayed onto the nanocone photovoltaic/solar elements. A contact transfer release sheet is then bonded to the clear conductive coating. Alternatively, clear plastic may be used to seal the clear conductive coating. The sheet may then be cut into individual nanocone photovoltaic/solar cells.

An apparatus for carrying out the above described process includes a load roll of plastic sheet that is transferred about a path. The sheet transfers past a shield and gets sprayed by a conductive paint spray which sprays conductive paint onto the sheet. The sheet then transfers passed a shield and gets sprayed by a glue spray which sprays a thin layer of dielectric glue onto the conductive paint.

The sheet then transfers past the shield and transfers between a belt and a metal plate. Below the belt is another metal plate. A suitable high voltage is applied between the plates so they function as electrodes. The belt carries nanocone photovoltaic/solar elements that have been prepared and dried as described above. The nanocone photovoltaic/solar elements, upon entering the electric field between the two electrodes, stand up and align with the electric field. The nanocone photovoltaic/solar elements then become charged, fly upward, and stick their bottom conductive tips into the dielectric glue that has been sprayed onto the sheet, and make contact with the conductive paint. The sheet then transfers past heat lamps which heat activate the glue and conductive paint, and more securely adhere the nanocone photovoltaic/solar elements to the glue and the conductive paint. The heat lamps also photoactivate the nanocone photovoltaic/solar elements.

The sheet is then transferred past a shield. After passing the shield, a clear conductive coating spray sprays clear conductive coating onto the photoactivated nanocone photovoltaic/solar elements. The sheet then transfers past a shield and past heat lamps. Each shield allows for no glue and no clear conductive coating on a predetermined distance from each edge of the sheet. The heat lamps further heat activate the materials on the sheet and further photoactivate the nanocone photovoltaic/solar elements.

The sheet then transfers past a contact roll. The contact roll bonds a contact transfer release sheet to the clear conductive coating sprayed onto the nanocone photovoltaic/solar elements by the clear conductive coating spray. The contact release sheet may have clear silicon applied thereto. The contact release sheet goes on the sheet and leaves a predetermined distance from each edge of sheet uncovered. As an alternative to employing the contact transfer release sheet, the sheet may be sealed in a clear plastic. The contact transfer release sheet is removed from the contact transfer release roll. After the contact transfer release sheet is bonded to the sheet, the sheet is transferred past a cutter which cuts the sheet into individual nanocone photovoltaic/solar cells.

Accordingly, it is a principal aspect of the invention to provide a nano photovoltaic/solar cell that includes a layer of plastic, conductive paint on the layer of plastic, glue on the conductive paint, nanocone photovoltaic/solar elements on the glue, clear conductive coating on the nanocone photovoltaic/solar elements, and a contact transfer release sheet on the clear conductive coating.

It is another aspect of the invention to provide a nano photovoltaic/solar cell that includes a nanocone photovoltaic element having a conductive bottom, a P type layer on the conductive bottom, an N type layer on the P type layer, and a clear conductive top on the N type layer, wherein more than one P and N junction may be included between the conductive bottom and clear conductive top.

It is a further aspect of the invention to provide a method of producing nano photovoltaic/solar cells including providing a sheet of plastic, spraying the sheet of plastic with a conductive paint, spraying the conductive paint with glue, attaching nanocone photovoltaic/solar elements in the glue to make contact with the conductive paint, spraying the nanocone photovoltaic/solar elements with a clear conductive coating, bonding another sheet on the clear conductive coating, and cutting the sheet of plastic after the bonding into individual nanocone photovoltaic solar cells.

Still another aspect of the invention is to provide an apparatus for manufacturing a nano photovoltaic/solar cell that includes a die with openings defined therein, a load roll of plastic sheet, a plurality of shields, a first conductive paint spray configured to spray conductive paint, a glue spray configured to spray glue, a belt configured to convey nano photovoltaic/solar elements, at least two metal plates configured to have a voltage applied between the at least two metal plates, a first plurality of heat lamps, a second conductive paint spray configured to spray clear conductive paint, a second plurality of heat lamps, a contact roll configured to bond a transfer release sheet to plastic sheet from the load roll, and a cutter configured to cut plastic sheet from the load roll.

It is an aspect of the invention to provide improved elements and arrangements thereof in nano photovoltaic/solar cells for the purposes described which is inexpensive, dependable and fully effective in accomplishing its intended purposes.

These and other aspects of the present invention will become readily apparent upon further review of the following specification and drawings.

### BRIEF DESCRIPTION OF THE DRAWINGS

FIG. 1 is a front view of a nanocone photovoltaic/solar element according to the present invention.

FIG. 2A is a top view of a die for producing nanocone photovoltaic/solar elements according to the invention.

FIG. 2B is a cross-sectional side view of the die shown in FIG. 2A.

FIG. 3 is a side view of a plastic sheet that has been sprayed with glue and upon which are attached nanocone photovoltaic/solar elements according-to the invention.

FIG. 4 is a top view of a nano photovoltaic/solar cell according to the invention.

FIG. 5 is a side view of an apparatus for carrying out a process for producing nano photovoltaic/solar cells according to the invention.

Similar reference characters denote corresponding features consistently throughout the attached drawings.

### DETAILED DESCRIPTION OF THE PREFERRED EMBODIMENTS

The present invention are nano photovoltaic/solar cells. The invention disclosed herein is, of course, susceptible of embodiment in many different forms. Shown in the drawings and described hereinbelow in detail are preferred embodiments of the invention. It is to be understood, however, that the present disclosure is an exemplification of the principles of the invention and does not limit the invention to the illustrated embodiments.

Nano photovoltaic/solar cells according to the invention each include a layer of plastic, conductive paint on the plastic sheet, glue on the conductive paint, nanocone photovoltaic/solar elements on the glue, clear conductive coating on the nanocone photovoltaic/solar elements, and a contact transfer release sheet on the nanocone photovoltaic/solar elements.

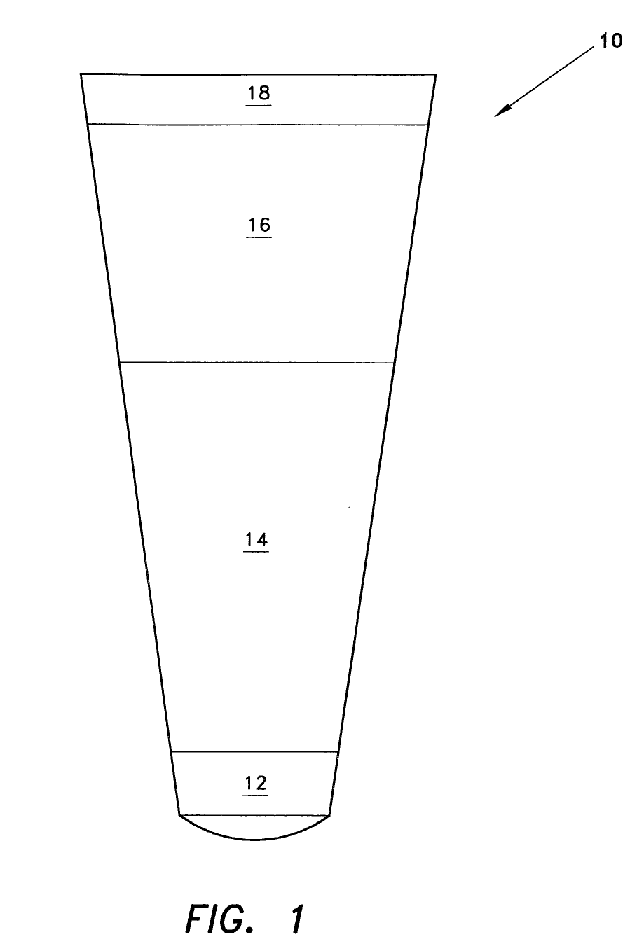

As shown in FIG. 1, each nanocone photovoltaic element 10 includes a conductive bottom 12, a P type layer 14 on the conductive bottom 12, an N type layer 16 on the P type layer 14, and a clear conductive top 18 on the N type layer. The nanocone photovoltaic element 10 may include more than one P and N junction between conductive bottom 12 and clear conductive top 18.

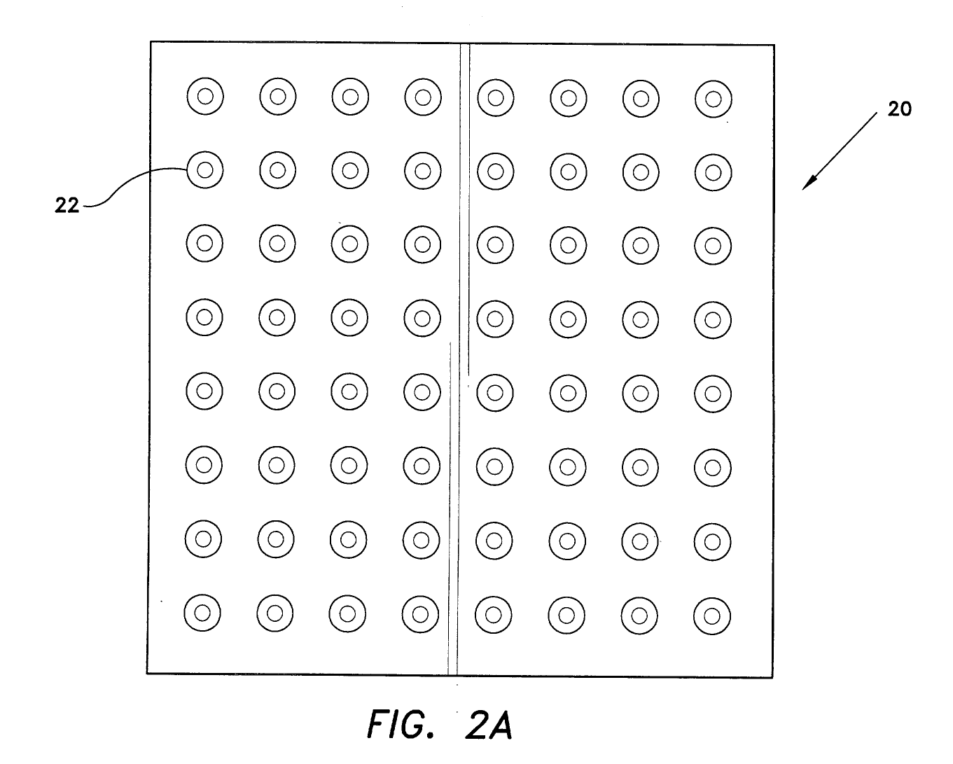

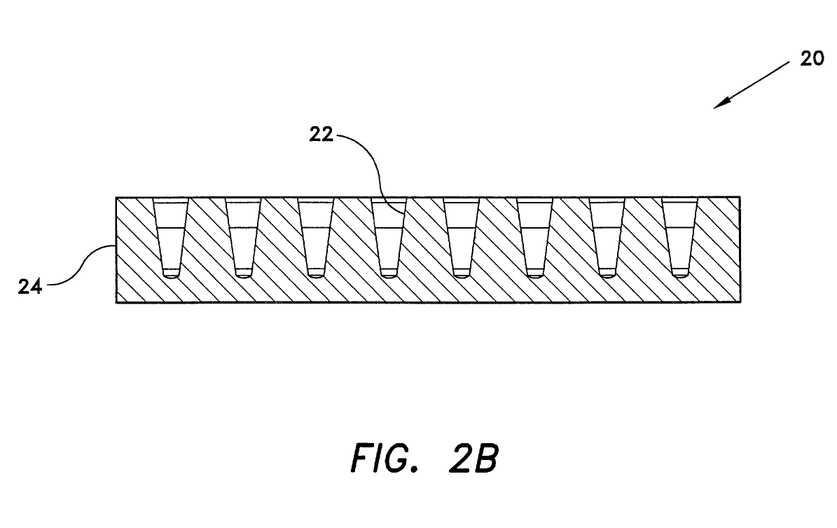

The nanocone photovoltaic/solar elements 10 are produced by employing a die 20 (see FIGS. 2A and 2B) with openings 22 defined therein that are configured in the form of cones each having a rounded bottom and a side that ends at an opening on a surface of die 20. Die 20 may include any number of cone shaped openings 22 defined therein. The bottom of opening 22 has a smaller diameter than the diameter of the top of opening 22. The nanocone photovoltaic/solar elements 10 are created by pouring in molten materials into die 20, injecting into die 20 materials in a vapor stage, placing die 20 in an environment that includes a vapor cloud, or by pressing in heated materials in die 20. Materials that may be used as conductive bottom 12 include copper, brass, aluminum, molybdenum, or another conductive material.

A P type layer 14 is formed by pouring in, injecting in, or hot pressing in, a P type material such as cadmium selenium (CdSe), P doped silicon, P doped gallium, or another P type material, such as ink or dye as described in U.S. Pat. No. 6,013,871, in die 20 over conductive bottom 12. An N type layer 16 is formed by pouring in, injecting in, or hot pressing in, an N type material such as cadmium sulfate (CdS), N doped silicon, N doped gallium, or another N type of material, such as dye or ink as described in U.S. Pat. No. 6,013,870, in the die over P type layer 14.

A clear conductive top layer 18 is formed by pouring in, injecting in, vapor depositing in, or hot pressing in, a clear conductive material such as zinc oxide doped with aluminum or another clear conductive material in die 20 on N type layer 16. This process in not limited to a single junction such as described above but may include multiple N and P junctions using different materials between conductive bottom 12 and clear conductive top 18 if desirable. The materials may be amorphous, polycrystal, or single crystal in their structure. The nanocone photovoltaic/solar elements 10 are then flushed out of die 20 and dried.

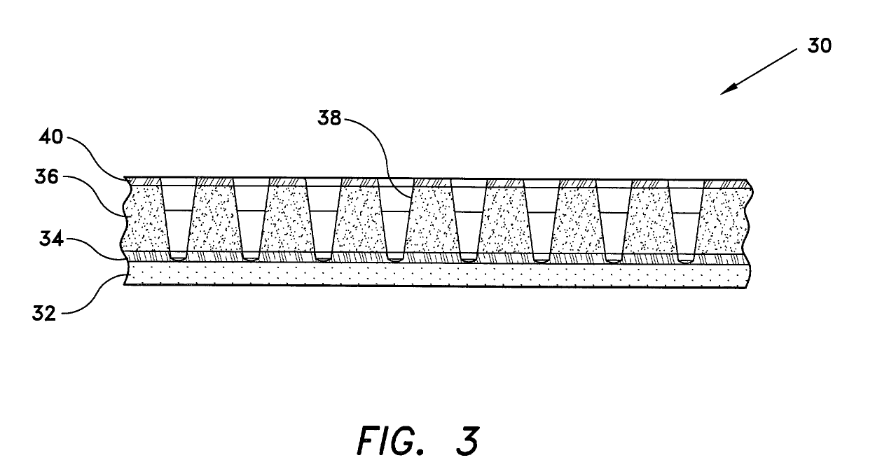

Once nanocone photovoltaic/solar elements 10 are produced, nano photovoltaic/solar cells may be manufactured by the following steps. Initially, a sheet of plastic is provided and the sheet is sprayed with a conductive paint. Glue is then sprayed on the conductive paint. Nanocone photovoltaic/solar elements are then attached to the glue and made to contact the conductive paint. Clear conductive coating is then sprayed onto the nanocone photovoltaic/solar elements. FIG. 3 illustrates a cross-section of a sheet 30 after these steps upon which a layer of conductive paint 34 is sprayed onto a sheet of plastic 32, a layer of glue 36 is sprayed on the conductive paint 34, nanocone photovoltaic/solar elements 38 are attached into the glue to contact the conductive paint 34, and a clear conductive coating 40 is sprayed on the glue 36 and the tops of nanocone photovoltaic elements 38.

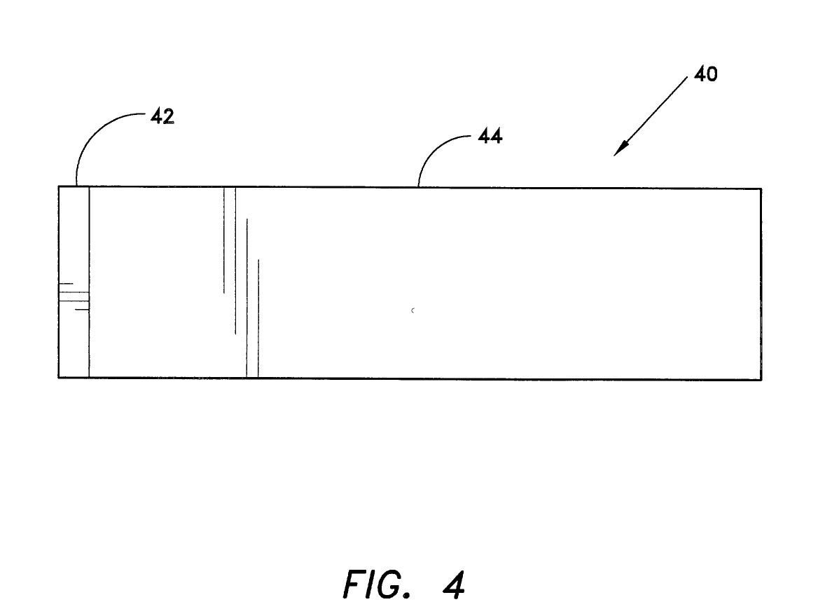

A contact transfer release sheet is then bonded to the clear conductive coating. Alternatively, clear plastic may be used to seal the clear conductive coating. The sheet may then be cut into individual nanocone photovoltaic/solar cells. FIG. 4 illustrates a top view of a nano photovoltaic/solar cell 40 according to the invention. Nano photovoltaic/solar cell 40 includes release sheet or clear plastic 44 and an uncovered edge 42.

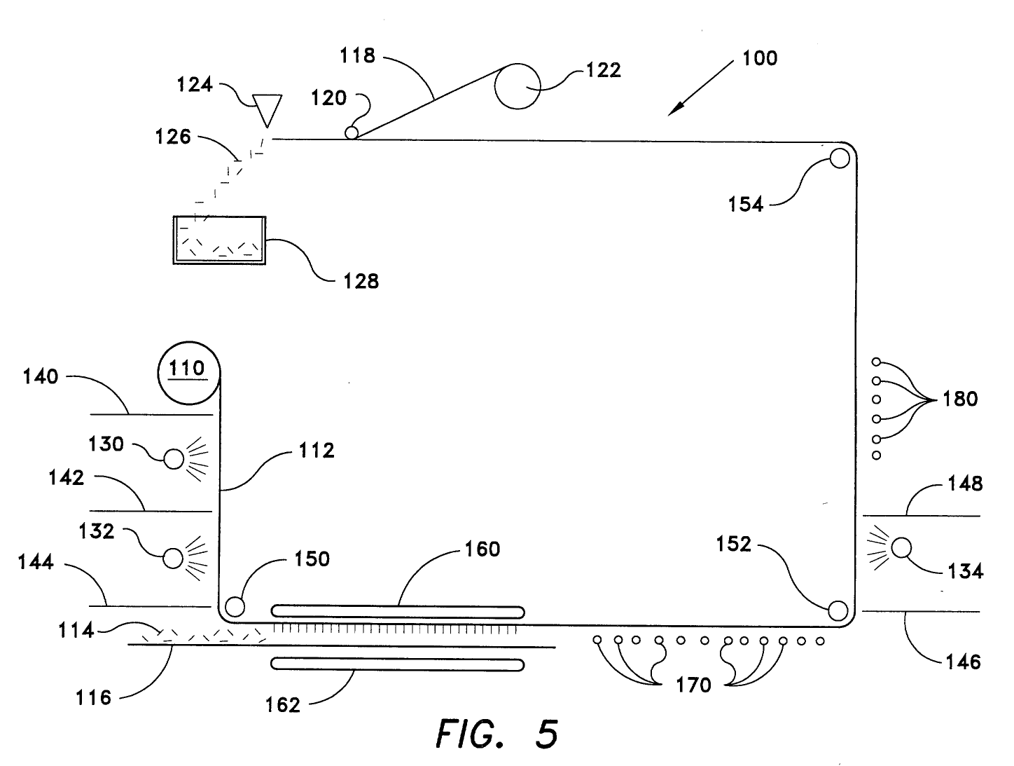

As shown in FIG. 5, an apparatus 100 is shown for carrying out the above described process. A load roll 110 of plastic sheet 112 transfers about a path defined by rolls 150, 152, and 154. Sheet 112 transfers past shield 140 and gets sprayed by a conductive paint spray 130 which sprays conductive paint onto sheet 112. Sheet 112 then passes shield 142 and gets sprayed by a glue spray 132 which sprays a thin layer of dielectric glue onto the conductive paint.

Sheet 112 then transfers past shield 144 and is redirected by contact roll 150 to transfer between a belt 116 and a metal plate 160. Below belt 116 is another metal plate 162. A suitable high voltage is applied between plates 160 and 162 so they function as electrodes. Belt 116 carries nanocone photovoltaic/solar elements 114 that have been prepared and dried as described above. Nanocone photovoltaic/solar elements 114, upon entering the electric field between electrodes 160 and 162, stand up and align with the electric field. Nanocone photovoltaic/solar elements 114 then become charged and fly upward and stick their bottom conductive tips into the dielectric glue and in contact with the conductive paint that has been sprayed onto sheet 112. Sheet 112 then transfers past heat lamps 170 which heat activate the glue and the conductive paint, and more securely adhere nanocone photovoltaic/solar elements 114 to the glue and the conductive paint. Heat lamps 170 also photoactivate nanocone photo-voltaic/solar elements 114.

Sheet 112 is then redirected by contact roll 152 and transfers past shield 146. After passing shield 146, clear conductive coating spray 134 sprays clear conductive coating onto photo-activated nanocone photovoltaic/solar elements 114. Sheet 112 then transfers past shield 148 and past heat lamps 180. Shields 140, 142, 144, and 148 allow for no glue and no clear conductive coating on a predetermined distance from each edge of sheet 112, such as ¼ inch or the like. Heat lamps 180 further heat activate the materials on sheet 112 and further photoactivate nanocone photovoltaic/solar elements 114.

Sheet 112 then transfers past contact roll 154 and is redirected to transfer past contact roll 120. Contact roll 120 bonds contact transfer release sheet 118 to the clear conductive coating sprayed onto nanocone photovoltaic/solar elements 114 by clear conductive coating spray 134. Contact release sheet 118 may have clear silicon applied thereto. Contact release sheet goes on sheet 112 and leaves a predetermined distance from each edge of sheet uncovered, such as ¼ inch or the like. Contact transfer release sheet 118 is removed from contact transfer release roll 122. As an alternative to employing contact transfer release sheet 118, sheet 112 may be sealed in a clear plastic. After contact transfer release sheet 118 is bonded to sheet 112, sheet 112 is transferred past cutter 124 which cuts sheet 112 into individual nano photovoltaic/solar cells 126. The configuration of apparatus 100 may obviously be changed so that it is straight rather than going around corners.

In nano photovoltaic/solar cells according to the invention, there is no light loss through diffusion, dispersion, or reflection. One hundred percent of the light that hits the nano photovoltaic/solar cell's top is utilized. The light that travels down the nano photovoltaic/solar cell activates the cell. By creating multiple P and N junctions between the clear conductive bottom and top, or stacking, it is possible to reach efficiencies approaching eighty percent.

While the invention has been described with references to its preferred embodiment, it will be understood by those skilled in the art that various changes may be made and equivalents may be substituted for elements thereof without departing from the true spirit and scope of the invention. In addition, many modifications may be made to adapt a particular situation or material to the teaching of the invention without departing from its essential teachings.

I claim:

1. A nano photovoltaic/solar cell comprising:
a layer of plastic;
a conductive paint on the layer of plastic;
glue on the conductive paint;
nanocone photovoltaic/solar elements on the glue;
a clear conductive coating on the nanocone photovoltaic/solar elements; and
a sheet on the clear conductive coating.

2. The nano photovoltaic/solar cell according to claim 1, wherein said layer of plastic is a plastic sheet.

3. The nano photovoltaic/solar cell according to claim 1, wherein said glue is dielectric.

4. The nano photovoltaic/solar cell according to claim 1, wherein said nanocone photovoltaic/solar elements each comprise:
a conductive bottom;
a clear conductive top; and
at least one P and N junction between said conductive bottom and said clear conductive top, wherein a P type layer contacts said conductive bottom and an N type layer contacts said clear conductive top.

5. The nano photovoltaic/solar cell according to claim 4, wherein said conductive bottom is selected from the group consisting of copper, brass, aluminum, and molybdenum.

6. The nano photovoltaic/solar cell according to claim 4, wherein said P type layer is material selected from the group consisting of cadmium selenium, P doped silicon, and P doped gallium.

7. The nano photovoltaic/solar cell according to claim 4, wherein said N type layer is material selected from the group consisting of cadmium sulfate, N doped silicon, and N doped gallium.

8. The nano photovoltaic/solar cell according to claim 4, wherein said clear conductive top is zinc oxide doped with aluminum.

9. The nano photovoltaic/solar cell according to claim 1, wherein said sheet on said clear conductive coating is a contact transfer release sheet.

10. The nano photovoltaic/solar cell according to claim 1, wherein said sheet on said clear conductive coating is a clear plastic sheet.

11. A method for producing a nano photovoltaic/solar cell, the method comprising:
providing a sheet of plastic;
spraying the sheet of plastic with a conductive paint;
spraying the conductive paint with glue;
attaching nanocone photovoltaic/solar elements in the glue so the nanocone photovoltaic/solar elements contact the conductive paint;
spraying the nanocone photovoltaic/solar elements with a clear conductive coating;
bonding another sheet on the clear conductive coating;
cutting the sheet of plastic after the bonding step into individual nano photovoltaic/solar cells.

12. The method for producing a nano photovoltaic/solar cell according to claim 11, wherein said bonding step further comprises providing a contact transfer sheet as said another sheet.

13. The method for producing a nano photovoltaic/solar cell according to claim 11, wherein said bonding step further comprises providing a clear plastic sheet as said another sheet.

14. An apparatus for manufacturing a nano photovoltaic/solar cell, said apparatus comprising:
a die with openings defined therein;
a load roll of plastic sheet;
a plurality of shields;
a first conductive paint spray configured to spray conductive paint;
a glue spray configured to spray glue;
a belt configured to convey nanocone photovoltaic/solar elements;
at least two metal plates configured to have a voltage applied between said at least two metal plates;
a first plurality of heat lamps;
a second conductive paint spray configured to spray clear conductive paint;
a second plurality of heat lamps;
a contact roll configured to bond a transfer release sheet to plastic sheet from said load roll; and
a cutter configured to cut plastic sheet from said load roll.

15. The apparatus for manufacturing a nano photovoltaic/solar cell according to claim 14, wherein said die has openings defined therein that are each configured in a form of a cone having a rounded bottom and a side that ends at an opening on a surface of said die.
